(19) United States
(12) Patent Application Publication
(10) Pub. No.: US 2016/0294325 A1
(43) Pub. Date: Oct. 6, 2016

(54) BROADBAND AMPLIFIER

(71) Applicant: FUJITSU LIMITED, Kawasaki-shi (JP)

(72) Inventor: Nikola NEDOVIC, San Jose, CA (US)

(21) Appl. No.: 14/673,603

(22) Filed: Mar. 30, 2015

(51) Int. Cl. H03F 1/02; G06F 17/50; H03F 3/04

(52) U.S. Cl. CPC H03F 1/0205; H03F 3/04; G06F 17/5072; H03F 2200/135

(57) ABSTRACT

A circuit may include an input node, a first intermediate node, a second intermediate node and an output node. The circuit may also include a first gain stage electrically coupled between the input node and the first intermediate node. Additionally, the circuit may include a second gain stage electrically coupled between the first intermediate node and the second intermediate node. Further, the circuit may include a third gain stage electrically coupled between the second intermediate node and the output node. The circuit may also include a first feedback that includes a first feedback element electrically coupled between the first intermediate node and the second intermediate node. In addition, the circuit may include a second feedback that includes a second feedback element electrically coupled between the output node and the first intermediate node.

### FIELD

The embodiments discussed herein are related to broadband amplifiers.

### BACKGROUND

Broadband amplifiers may be used for a myriad of applications in high-speed analog and mixed-signal circuits. Broadband amplifiers may have target design specifications in which the broadband amplifiers may be specified as having a relatively high bandwidth and a relatively high gain. Many current designs of broadband amplifiers consume a relatively large amount of power to achieve the target specifications. However, some applications of broadband amplifiers (e.g., nanometer range complimentary metal-oxide semiconductor (CMOS) processes) may include low power specifications for the corresponding broadband amplifiers.

The subject matter claimed herein is not limited to embodiments that solve any disadvantages or that operate only in environments such as those described above. Rather, this background is only provided to illustrate one example technology area where some embodiments described herein may be practiced.

### SUMMARY

According to an aspect of an embodiment, a circuit may include an input node, a first intermediate node, a second intermediate node and an output node. The circuit may also include a first gain stage that includes a first input electrically coupled to the input node and a first output electrically coupled to the first intermediate node. Additionally, the circuit may include a second gain stage that includes a second input electrically coupled to the first intermediate node and a second output electrically coupled to the second intermediate node. Further, the circuit may include a third gain stage that includes a third input electrically coupled to the second intermediate node and a third output electrically coupled to the output node. The circuit may also include a first feedback that includes a first feedback element electrically coupled between the first intermediate node and the second intermediate node. In addition, the circuit may include a second feedback that includes a second feedback element electrically coupled between the output node and the first intermediate node.

The object and advantages of the embodiments will be realized and achieved at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1A illustrates an example broadband amplifier circuit;

FIG. 1B illustrates an example broadband amplifier circuit that is an example implementation of the broadband amplifier circuit of FIG. 1A;

FIG. 1C illustrates example root locus diagrams for the broadband amplifier circuit of FIG. 1B;

FIG. 2 is a flowchart of an example method of performing broadband amplification; and

FIG. 3 is a flowchart of an example of designing a broadband amplifier circuit.

### DESCRIPTION OF EMBODIMENTS

According to an aspect of an embodiment, a broadband amplifier circuit (referred to hereinafter as “the circuit”) may include a nested feedback and a global feedback that feedback to the same node in the circuit. The global feedback may have a non-negligible delay with respect to the nested feedback such that its corresponding global feedback signal may have a phase shift with respect to a nested feedback signal that corresponds to the nested feedback. As described below, the delay may create a peaking of voltage at the node in a manner that may at least partially compensate for leveling of the signal that may be caused by a filtering of high frequency components of the signal. As such, the peaking may increase the bandwidth of the broadband amplifier. Further, the configuration described below may consume less power than other implementations of broadband amplifiers.

Embodiments of the present disclosure will be explained with reference to the accompanying drawings.

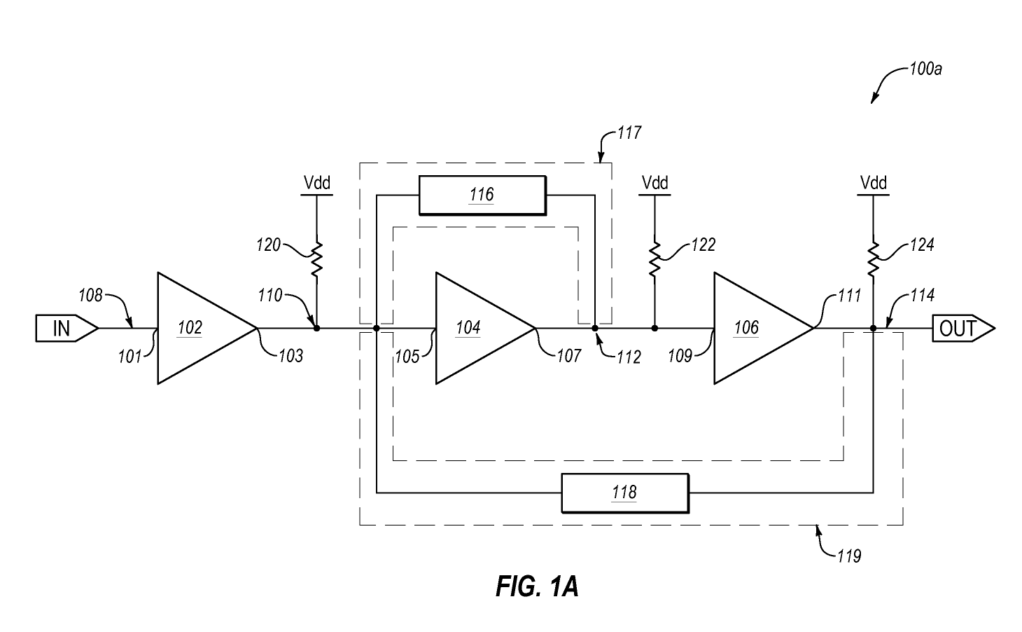

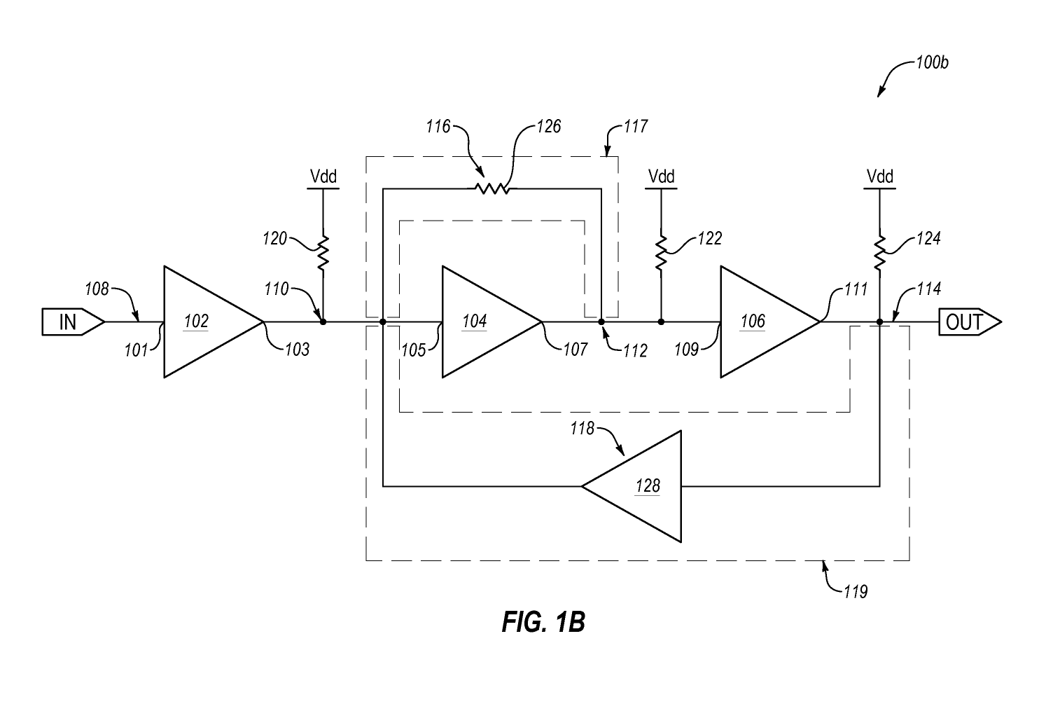

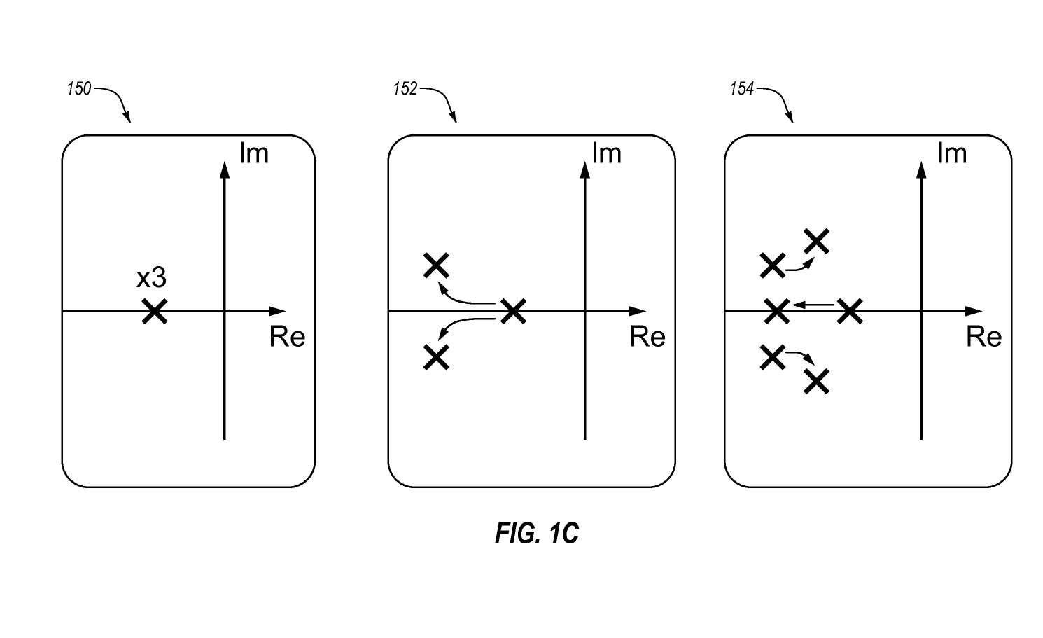

FIG. 1A illustrates an example broadband amplifier circuit 100a (“the circuit 100a”), arranged in accordance with at least one embodiment described herein. The circuit 100a may include a first gain stage 102, a second gain stage 104, a third gain stage 106, a first feedback 117, and a second feedback 119. The circuit 100a may also include a voltage supply “Vdd” that may provide a voltage to one or more components of the circuit 100a as well as a voltage for biasing one or more nodes of the circuit 100a. The circuit 100a may include one or more other components than those specifically depicted.

The first gain stage 102 may be electrically coupled between an input node 108 and a first intermediate node 110 of the circuit 100a. The first gain stage 102 may include a first input 101 configured to receive an input signal at the input node 108. The first gain stage 102 may be configured to apply a first gain to the input signal to generate a first intermediate signal. The first gain stage 102 may also include a first output 103 configured to output the first intermediate signal at the first intermediate node 110. An absolute value of the first gain may be greater than or equal to one or less than one.

In some embodiments, the first gain stage 102 may include an inverting single-stage amplifier that may be configured to invert the input signal during generation of the first intermediate signal such that the first intermediate signal may be inverted with respect to the input signal. By way of example, the first gain stage 102 may include a common source n-type metal-oxide-semiconductor (nMOS) amplifier with a resistive load or a complementary metal-oxide-semiconductor (CMOS) inverter.

In these or other embodiments, the first gain stage 102 may be configured to convert a voltage signal into a current signal. For example, in some instances the input signal may be configured as a voltage signal and the first gain stage 102 may be configured as a transconductance amplifier to convert the input signal to a current signal such that the first intermediate signal is output as a current signal.

In some embodiments, the circuit 100a may include a resistive element (e.g., a resistor) 120 electrically coupled between the voltage supply “Vdd” and the first intermediate node 110. The resistive element 120 may be configured with respect to the voltage supply “Vdd” to bias the first intermediate node 110 with a target DC voltage.

The second gain stage 104 may be electrically coupled between the first intermediate node 110 and a second intermediate node 112 of the circuit 100. The second gain stage 104 may include a second input 105 configured to receive the first intermediate signal at the first intermediate node 110. The second gain stage 104 may be configured to apply a second gain to the first intermediate signal to generate a second intermediate signal. The second gain stage 104 may also include a second output 107 configured to output the second intermediate signal at the second intermediate node 112. An absolute value of the second gain may be greater than or equal to one or less than one.

In some embodiments, the second gain stage 104 may include an inverting single-stage amplifier that may be configured to invert the first intermediate signal during generation of the second intermediate signal such that the second intermediate signal may be inverted with respect to the first intermediate signal. By way of example, the second gain stage 104 may include a common source nMOS amplifier with a resistive load or a CMOS inverter.

The first feedback 117 may be configured as a nested feedback and may be electrically coupled between the first intermediate node 110 and the second intermediate node 112. Therefore, the second intermediate signal may be fed back to the first intermediate node 110 as a first feedback signal. The first feedback 117 may include a first feedback element 116 electrically coupled between the first intermediate node 110 and the second intermediate node 112 such that the first feedback signal may pass through the first feedback element 116. The first feedback element 116 may include a passive component (e.g., a resistor, a capacitor, or an inductor), an active component (e.g., a transistor, an amplifier, etc.), or any combination thereof.

In some embodiments (e.g., when the first gain stage 102 includes a transconductance amplifier), the first feedback element 116 may be configured to interact with the second gain stage 104 such that the second gain stage 104 and the first feedback element 116 are configured as a transimpedance amplifier. As such, the first feedback element 116 may be such that the first feedback 117 may generate the first feedback signal as a current-mode feedback. The current-mode feedback may be active or passive depending on whether or not the first feedback element 116 is active or passive.

By way of example, in some embodiments, the first feedback element 116 may include a passive component (e.g., a resistor), which together with the second gain stage 104 may act as a transimpedance amplifier with respect to signals received at the first intermediate node 110 and output at the second intermediate node 112 such that a passive current-mode feedback may be generated. As another example, in some embodiments, the first feedback element 116 may include an active component, which together with the second gain stage 104 may act as a transimpedance amplifier with respect to signals received at the first intermediate node 110 and output at the second intermediate node 112 such that an active current-mode feedback may be generated.

In some embodiments and as explained in further detail below, the first feedback 117 may change the frequency response (e.g., improve the bandwidth) of the circuit 100a. Additionally, the first feedback element 116 and its associated properties may be selected to better obtain a target frequency response of the circuit 100a, which is also described in further detail below.

In some embodiments, the circuit 100a may include a resistive element (e.g., a resistor) 122 electrically coupled between the voltage supply “Vdd” and the second intermediate node 112. The resistive element 122 may be configured with respect to the voltage supply “Vdd” to bias the second intermediate node 112 with a target DC voltage.

The third gain stage 106 may be electrically coupled between the second intermediate node 112 of the circuit 100a and an output node 114 of the circuit 110a. The third gain stage 106 may include a third input 109 configured to receive the second intermediate signal at the second intermediate node 112. The third gain stage 106 may be configured to apply a third gain to the second intermediate signal to generate an output signal. The third gain stage 106 may also include a third output 111 configured to output the output signal at the output node 114. An absolute value of the third gain may be greater than or equal to one or less than one.

In some embodiments, the third gain stage 106 may include an inverting single-stage amplifier that may be configured to invert the second intermediate signal during generation of the output signal such that the output signal may be inverted with respect to the second intermediate signal. By way of example, the third gain stage 106 may include a common source nMOS amplifier with a resistive load or CMOS inverter.

In these or other embodiments (e.g., when the second gain stage 104 and the first feedback element 116 are configured as a transimpedance amplifier), the third gain stage 106 may be configured to convert a voltage signal into a current signal. For example, in some instances the second intermediate signal may be configured as a voltage signal and the third gain stage 106 may be configured as a transconductance amplifier to convert the second intermediate signal to a current signal such that the output signal is output as a current signal.

In some embodiments, the circuit 100a may include a resistive element (e.g., a resistor) 124 electrically coupled between the voltage supply “Vdd” and the output node 114. The resistance of the resistive element 124 may be configured with respect to the voltage supply “Vdd” to bias the output node 114 with a target DC voltage.

The second feedback 119 may be configured as a global feedback and may be electrically coupled between the first intermediate node 110 and the output node 114. Therefore, the second feedback 119 may feed the output signal back to the intermediate node 110 as a second feedback signal. The second feedback 119 may include a second feedback element 118 electrically coupled between the first intermediate node 110 and the output node 114 such that the second feedback signal may pass through the second feedback element 118.

The second feedback element 118 may include a passive component (e.g., a resistor), an active component (e.g., a transistor, an amplifier, etc.), or any combination thereof. The second feedback element 118 may be such that the second feedback 119 may generate the second feedback signal as an active current-mode feedback in some embodiments or as a passive current-mode feedback in other embodiments. The current-mode feedback of the second feedback signal may be active or passive depending on whether or not the second feedback element 118 is an active or passive.

Further, the second feedback element 118 may be selected and/or configured such that it may delay the output signal that may be fed back from the output node 114 to the first intermediate node 110 such that the second feedback element 118 may introduce a phase shift in the second feedback signal as compared to the output signal and as compared to the first feedback signal. The phase shift of the second feedback signal may be such that the second feedback signal, when added to the first intermediate signal, may create a peaking in the first intermediate signal at the first intermediate node 110. The peaking of the first intermediate signal at the first intermediate node 110 may at least partially compensate for signal leveling that may be caused by a filtering of high frequency components by elements (e.g., the first gain stage 102, the second gain stage 104, and/or the third gain stage 106) of the circuit 100a. As such, the peaking may increase the bandwidth of the circuit 100a. Further, the second feedback element 118 and its associated properties may be selected to better obtain the target frequency response of the circuit 100a, which is described in further detail below.

Therefore, the configuration of the circuit 100a in the manner illustrated and disclosed may allow for an increased bandwidth for the circuit 100a as compared to that of other circuits that may be configured as broadband amplifiers. Modifications, additions, or omissions may be made to the circuit 100a without departing from the scope of the present disclosure. For example, the circuit 100a may include any number of components other than those specifically illustrated and/or mentioned. Further, the selection of specific components for specific elements (e.g., for the first feedback element 116 and/or the second feedback element 118) may vary depending on specific implementations and target specifications. Additionally, in some embodiments, one or more portions of the circuit 100a may be configured to operate with respect to differential signals and/or single-ended signals.

FIG. 1B illustrates an example broadband amplifier circuit 100b (“the circuit 100a”) that is an example implementation of the circuit 100a of FIG. 1A, arranged in accordance with at least one embodiment described herein. The circuit 100b may include the voltage supply “Vdd,” the input node 108, the first gain stage 102, the first intermediate node 110, the resistive element 120, the second gain stage 104, the second intermediate node 112, the resistive element 122, the third gain stage 106, the resistive element 124, the output node 114, the first feedback 117, and the second feedback 119, as described above with respect to the circuit 100a of FIG. 1A.

In FIG. 1B, a resistive element 126 (e.g., a resistor) is illustrated as an example of the first feedback element 116 of the first feedback 117. The resistive element 126 may include a passive resistive element such as a resistor or may include an active resistive element such as a transistor. Additionally, in some embodiments, the resistive element 126 may include an adjustable resistive element or a fixed resistive element.

Additionally, in FIG. 1B, an amplifier 128 is illustrated as an example of the second feedback element 118 of the second feedback 119. In some embodiments, the amplifier 128 may include an inverting single-stage amplifier that may be configured to invert the second feedback signal with respect to the output signal. By way of example, the amplifier 128 may include a common source nMOS amplifier with a resistive load or CMOS inverter. Additionally or alternatively, in some embodiments, the amplifier 128 may include a variable gain amplifier or a fixed gain amplifier.

Different resistances of the resistive element 126 and different gains of the amplifier 128 may change the frequency response of the circuit 100b. Therefore, in some embodiments, the resistance of the resistive element 126 and/or the gain of the amplifier 128 may be selected and/or adjusted according to a target frequency response of the circuit 100b. For example, in some embodiments, the resistance of the resistive element 126 and/or the gain of the amplifier 128 may be selected and/or adjusted such that the frequency response of the circuit 100b is equal to or approximately equal to the target frequency response.

By way of example, FIG. 1C illustrates example root locus diagrams for the circuit 100b that illustrate how the frequency response of the circuit 100b may be affected by the resistance of the resistive element 126 and the gain of the amplifier 128, according to at least one embodiment described herein. Specifically, FIG. 1C includes a root locus diagram 150, a root locus diagram 152, and a root locus diagram 154, of the circuit 100b.

The root locus diagram 150 illustrates an example location of poles of a transfer function of the circuit 100b when the resistance of the resistive element 126 is approximately infinite and the gain of the amplifier 128 is approximately zero such that it is as if the first feedback 117 and the second feedback 119 are non-existent. In this particular example, three poles of the transfer function are illustrated may be together at approximately the same location along the real axis (Re) of the root locus diagram.

The root locus diagram 152 illustrates an example location and movement of poles of the transfer function of the circuit 100b when the resistance of the resistive element 126 is reduced to a finite value. For example, when the resistance of the resistive element 126 is reduced, two poles of the transfer function may move along the real axis of the root locus diagram away from the origin of the root locus diagram. Additionally, when the resistance of the resistive element 126 is reduced, the two poles may move away from each other along the imaginary (Im) axis of the root locus diagram such that they may become complex conjugates of each other, as illustrated in the root locus diagram 152. Further, in this particular example, the third pole may maintain its position.

The root locus diagram 154 illustrates an example location and movement of poles of the transfer function of the circuit 100b when the gain of the amplifier 128 is moved away from zero. For example, when the gain of the amplifier 128 is moved away from zero, the complex conjugate poles of the transfer function may move along the real axis of the root locus diagram toward the origin of the root locus diagram. Additionally, when the gain of the amplifier 128 is moved away from zero, the complex conjugate poles may move further away from each other along the imaginary axis of the root locus diagram. Further, in this particular example, the third pole may move along the real axis away from the origin of the root locus diagram.

Different positions of the poles with respect to the imaginary and real axes of the root locus diagram may give different frequency responses of the circuit 100b. Therefore, in some embodiments, the resistance of the resistive element 126 and/or the gain of the amplifier 128 may be adjusted or determined such that the position of the poles in the root locus diagram correspond to or approximately correspond to the target frequency response of the circuit 100b.

Therefore, the configuration of the circuit 100b in the manner illustrated and disclosed may allow for an improved frequency response for the circuit 100b as compared to that of other circuits that may be configured as broadband amplifiers. Additionally, as illustrated above, one or more elements and their associated properties of the circuit 100b (e.g., the resistive element 126 and the amplifier 128) may be adjusted or selected to obtain or approximately obtain a target frequency response of the circuit 100b.

Modifications, additions, or omissions may be made to the circuit 100b without departing from the scope of the present disclosure. For example, the circuit 100b may include any number of components other than those specifically illustrated and/or mentioned. Further, the selection of specific components for specific elements (e.g., for the first feedback element 116 and/or the second feedback element 118) may vary depending on specific implementations and target specifications. For example, in some embodiments, the first feedback element 116 may include an amplifier and/or the second feedback element 118 may include a resistive element. Additionally, the transfer function of the circuit 100a may include one or more zeros and/or one or more other poles than those explicitly illustrated in FIG. 1C. Additionally, in some embodiments, one or more portions of the circuit 100b may be configured to operate with respect to differential signals and/or single-ended signals.

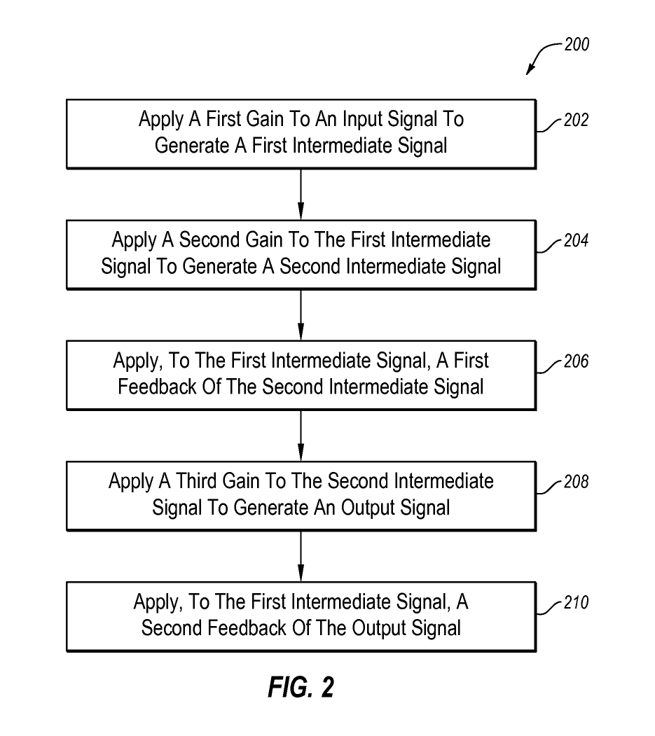

FIG. 2 is a flowchart of an example method 200 of obtaining broadband amplification, in accordance with at least one embodiment described herein. The method 200 may be implemented and performed, in some embodiments, by a broadband amplifier circuit, such as the circuits 100a and 100b described above. Although illustrated as discrete blocks, various blocks may be divided into additional blocks, combined into fewer blocks, or eliminated, depending on the implementation

The method 200 may begin at block 202 where a first gain may be applied to an input signal to generate a first intermediate signal. For example, the first gain may be applied by a first gain stage such as the first gain stage 102 of the circuits 100a and 100b. Additionally or alternatively, block 202 may include inverting the input signal during generation of the first intermediate signal such that the first intermediate signal may be inverted with respect to the input signal.

At block 204, a second gain may be applied to the first intermediate signal to generate a second intermediate signal. For example, the second gain may be applied by a second gain stage such as the second gain stage 104 of the circuits 100a and 100b. Additionally or alternatively, block 204 may include inverting the first intermediate signal during generation of the second intermediate signal such that the second intermediate signal may be inverted with respect to the first intermediate signal.

At block 206, a third gain may be applied to the second intermediate signal to generate an output signal. For example, the third gain may be applied by a third gain stage such as the third gain stage 106 of the circuits 100a and 100b. Additionally or alternatively, block 206 may include inverting the second intermediate signal during generation of the output signal such that the output signal may be inverted with respect to the second intermediate signal.

At block 208, a first feedback of the second intermediate signal may be applied to the first intermediate signal as a first feedback signal of the first intermediate signal. In some embodiments, the first feedback signal may pass through a first feedback element of the first feedback before being applied to the first intermediate signal. In some embodiments, the first feedback element may include a resistive element. Additionally or alternatively, one or more properties of the first feedback element may be adjusted according to a target frequency response.

At block 210, a second feedback of the output signal may be applied to the first intermediate signal as a second feedback signal of the first intermediate signal. In some embodiments, the second feedback signal may pass through a second feedback element of the second feedback before being applied to the first intermediate signal. In some embodiments, the second feedback element may include an amplifier such that a gain may be applied to the second feedback signal. Additionally or alternatively, one or more properties of the second feedback element may be adjusted according to a target frequency response.

One skilled in the art will appreciate that, for the method 200 and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

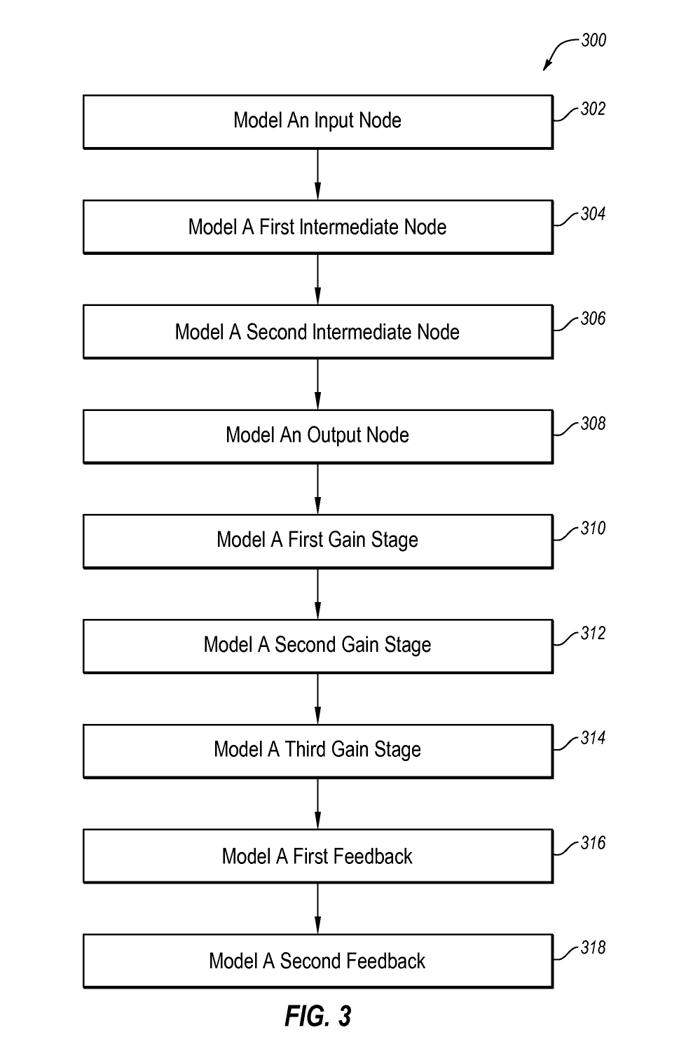

FIG. 3 is a flowchart of an example method 300 of designing a broadband amplifier circuit, arranged in accordance with at least one embodiment described herein. The method 300 may be implemented, in some embodiments, using any applicable design software stored on a computer-readable storage medium that may include instructions that when executed by one or more processors may cause a system to perform the operations described with respect to FIG. 3. In some embodiments, designing of the broadband amplifier circuit may be done according to the principles described above with respect to the circuits 100a and 100b, of FIGS. 1A and 1B, respectively. Although illustrated as discrete blocks, various blocks may be divided into additional blocks, combined into fewer blocks, or eliminated, depending on the implementation.

The method 300 may begin and at block 302 an input node may be modeled. At block 304, a first intermediate node may be modeled. At block 306, a second intermediate node may be modeled. At block 308, an output node may be modeled.

At block 310, a first gain stage may be modeled, where the first gain stage may be modeled to include a first input electrically coupled to the input node and a first output electrically coupled to the first intermediate node. At block 312, a second gain stage may be modeled, where the second gain stage may be modeled to include a second input electrically coupled to the first intermediate node and a second output electrically coupled to the second intermediate node. At block 314, a third gain stage may be modeled, where the third gain stage may be modeled to include a third input electrically coupled to the second intermediate node and a third output electrically coupled to the output node.

At block 316, a first feedback that includes a first feedback element may be modeled. The first feedback may be modeled such that the first feedback element is electrically coupled between the first intermediate node and the second intermediate node. In some embodiments, the first feedback element may be modeled to include a passive or an active element. Additionally or alternatively, in some embodiments, the first feedback element may be modeled to include a resistive element. In these or other embodiments, the first feedback element may be modeled to include an amplifier. Further, in some embodiments, the first feedback element may be modeled as being adjustable. In these or other embodiments, one or more properties of the first feedback element may be adjusted according to a target frequency response of the broadband amplifier.

At block 318, a second feedback that includes a second feedback element may be modeled. The second feedback may be modeled such that the second feedback element is electrically coupled between the first intermediate node and the output node. In some embodiments, the second feedback element may be modeled to include a passive or an active element. Additionally or alternatively, in some embodiments, the second feedback element may be modeled to include a resistive element. In these or other embodiments, the second feedback element may be modeled to include an amplifier. Further, in some embodiments, the second feedback element may be modeled as being adjustable. In these or other embodiments, one or more properties of the second feedback element may be adjusted according to a target frequency response of the broadband amplifier.

One skilled in the art will appreciate that, for the method 300 and other processes and methods disclosed herein, the functions performed in the processes and methods may be implemented in differing order or simultaneously. Furthermore, the outlined steps and operations are only provided as examples, and some of the steps and operations may be optional, combined into fewer steps and operations, or expanded into additional steps and operations without detracting from the essence of the disclosed embodiments.

The method 300 described herein may be implemented using any suitable special-purpose or general-purpose computer, computing entity, or processing device including various computer hardware or software modules and may be configured to execute computer-executable instructions stored on any applicable computer-readable media. For example, the method 300 may be performed by one or more processors individually or collectively that may include a microprocessor, a microcontroller, a digital signal processor (DSP), an application-specific integrated circuit (ASIC), a Field-Programmable Gate Array (FPGA), or any other digital or analog circuitry configured to interpret and/or to execute program instructions and/or to process data.

Computer-readable media may be any available media that may be accessed by a general-purpose or special-purpose computer (e.g., a processor). By way of example, and not limitation, such computer-readable media may include a non-transitory or tangible computer-readable storage media including Random Access Memory (RAM), Read-Only Memory (ROM), Electrically Erasable Programmable Read-Only Memory (EEPROM), Compact Disc Read-Only Memory (CD-ROM) or other optical disk storage, magnetic disk storage or other magnetic storage devices, or any other storage medium which may be used to carry or store program code in the form of computer-executable instructions or data structures and which may be accessed by a general-purpose or special-purpose computer. Combinations of the above may also be included within the scope of computer-readable media. The computer-readable media may include computer-executable instructions which may include, for example, instructions and data that cause a general-purpose computer, special-purpose computer, or special-purpose processing device to perform a certain function or group of functions.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases at least one and one or more to introduce claim recitations. However, the use of such phrases should not be construed to imply that the introduction of a claim recitation by the indefinite articles “a” or an limits any particular claim containing such introduced claim recitation to embodiments containing only one such recitation, even when the same claim includes the introductory phrases one or more or at least one and indefinite articles such as “a” or an (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

All examples and conditional language recited herein are intended as pedagogical objects to aid the reader in understanding the invention and the concepts contributed by the inventor to furthering the art, and are to be construed as being without limitation to such specifically recited examples and conditions. Although embodiments of the present inventions have been described in detail, it should be understood that the various changes, substitutions, and alterations could be made hereto without departing from the spirit and scope of the invention.

What is claimed is:

1. A circuit comprising:
an input node;
a first intermediate node;
a second intermediate node;
an output node;
a first gain stage that includes a first input electrically coupled to the input node and a first output electrically coupled to the first intermediate node;
a second gain stage that includes a second input electrically coupled to the first intermediate node and a second output electrically coupled to the second intermediate node;
a third gain stage that includes a third input electrically coupled to the second intermediate node and a third output electrically coupled to the output node;
a first feedback that includes a first feedback element electrically coupled between the first intermediate node and the second intermediate node; and
a second feedback that includes a second feedback element electrically coupled between the output node and the first intermediate node.

2. The circuit of claim 1, wherein one or more of the first feedback element and the second feedback element includes a passive element.

3. The circuit of claim 2, wherein the passive element includes a resistive element.

4. The circuit of claim 1, wherein one or more of the first feedback element and the second feedback element includes an active element.

5. The circuit of claim 4, wherein the active element includes an amplifier.

6. The circuit of claim 1, wherein one or more of the following are configured to operate with respect to differential signals: the first gain stage, the second gain stage, the third gain stage, the first feedback element, and the second feedback element.

7. The circuit of claim 1, wherein one or more of the first gain stage, the second gain stage, and the third gain stage includes an inverting single-stage amplifier.

8. The circuit of claim 1, wherein one or more of the first feedback element and the second feedback element are configured according to a target frequency response.

9. The circuit of claim 1, wherein one or more of the first feedback element and the second feedback element is adjustable.

10. A method comprising:
applying a first gain to an input signal to generate a first intermediate signal;
applying a second gain to the first intermediate signal to generate a second intermediate signal;
applying a third gain to the second intermediate signal to generate an output signal
applying, to the first intermediate signal, a first feedback of the second intermediate signal as a first feedback signal of the first intermediate signal, wherein the first feedback includes a first feedback element through which the first feedback signal passes before being applied to the first intermediate signal; and
applying, to the first intermediate signal, a second feedback of the output signal as a second feedback signal of the first intermediate signal, wherein the second feedback includes a second feedback element through which the second feedback signal passes before being applied to the first intermediate signal.

11. The method of claim 10, further comprising adjusting one or more of the first feedback element and the second feedback element according to a target frequency response.

12. The method of claim 10, further comprising inverting one or more of the input signal, the first intermediate signal, and the second intermediate signal.

13. The method of claim 10, further comprising applying, by the second feedback element, a gain to the second feedback signal.

14. A method of designing a circuit, the method comprising:
modeling an input node;
modeling a first intermediate node;
modeling a second intermediate node;
modeling an output node;
modeling a first gain stage that includes a first input electrically coupled to the input node and a first output electrically coupled to the first intermediate node;
modeling a second gain stage that includes a second input electrically coupled to the first intermediate node and a second output electrically coupled to the second intermediate node;
modeling a third gain stage that includes a third input electrically coupled to the second intermediate node and a third output electrically coupled to the output node;
modeling a first feedback that includes a first feedback element electrically coupled between the first intermediate node and the second intermediate node; and
modeling a second feedback that includes a second feedback element electrically coupled between the output node and the first intermediate node.

15. The method of claim 14, further comprising modeling one or more of the first feedback element and the second feedback element to include a passive element.

16. The method of claim 15, further comprising modeling the passive element to include a resistive element.

17. The method of claim 14, further comprising modeling one or more of the first feedback element and the second feedback element to include an active element.

18. The method of claim 17, further comprising modeling the active element to include an amplifier.

19. The method of claim 14, further comprising adjusting one or more of the first feedback element and the second feedback element according to a target frequency response.

20. The method of claim 14, further comprising modeling one or more of the first feedback element and the second feedback element as being adjustable.
